(19) United States
(12) Patent Application Publication
(10) Pub. No.: US 2026/0090130 A1
(43) Pub. Date: Mar. 26, 2026

(54) Method for manufacturing a copper-free CdTe based thin film solar cell device

(71) Applicants: China Triumph International Engineering Co., Ltd., Shanghai (CN); CTF Solar GmbH, Dresden (DE)

(72) Inventors: Shou PENG, Shanghai (CN); YIN Xinjian, Shanghai (CN); Ganhua FU, Shanghai (CN); Liyun MA, Shanghai (CN); Robert ARNDT, Dresden (DE); Georgios PAPAGEORGIOU, Dresden (DE); Christian DROST, Dresden (DE); Marko SWOBODA, Dresden (DE)

(73) Assignees: China Triumph International Engineering Co., Ltd., Shanghai (CN); CTF Solar GmbH, Dresden (DE)

(21) Appl. No.: 19/111,802

(22) PCT Filed: Sep. 15, 2022
(86) PCT No.: PCT/CN2022/119060

§ 371 Date: Mar. 14, 2025

(51) Int. Cl. H10F 71/00; C23C 14/06; C23C 14/58; H10F 77/20

(52) U.S. Cl. CPC H10F 71/125; C23C 14/0629; C23C 14/5806; H10F 71/128; H10F 77/219

(57) ABSTRACT

A method for manufacturing a copper-free CdTe based thin film solar cell device, comprising the following steps: a) providing a substrate at least comprising a front electrode, b) depositing a CdTe based absorber layer, c) performing an activation treatment, d) applying a X-halogen to the CdTe based absorber layer, wherein X is selected out of a group consisting of P, As, Sb and V; e) performing a thermal treatment after step d) and f) depositing a back contact, characterized in that, the thermal treatment in step e) is performed before step f) and at temperatures in the range of 40° C. to 120° C. in inert atmosphere or vacuum for a duration in the range of 10 minutes to 60 minutes.

### FIELD OF TECHNOLOGY

The invention concerns a copper-free CdTe based thin film solar cell device.

### BACKGROUND

Copper as doping element in CdTe based thin film solar cell devices has some draw backs, like low device stability and charge carrier lifetime. Replacing copper as doping element is subject of many documents, for instance US 2021/0280735 A1.

US 2021/0280735 A1 comprises a method for ex-situ doping CdTe with P, As, Sb or Bi, wherein a CdTe film activated with CdCl₂ is contacted with a solution or vapour comprising P-halide, As-halide, Sb-halide or Bi-halide to provide a CdTe film doped with P, As, Sb or Bi.

### SUMMARY

Object of the invention is to provide an alternative method for manufacturing a copper-free CdTe based thin film solar cell device with improved photovoltaic efficiency.

The object is solved by a method according to the independent claim. Preferred embodiments are subject of the dependent claims.

According to the invention a method for manufacturing a copper-free CdTe based thin film solar cell device at least comprises the following steps
a) Providing a substrate at least comprising a front electrode,
b) Depositing a CdTe based absorber layer,
c) Performing an activation treatment,
d) Applying a X-halogen to the CdTe based absorber layer, wherein X is selected out of a group consisting of P, As, Sb and V,
e) Performing a thermal treatment after step d),
f) depositing a back contact,
characterized in that, the thermal treatment in step e) is performed before step f) and at a temperature in the range of 40° C. to 120° C. in an inert atmosphere or vacuum for a duration in the range of 10 minutes to 60 minutes.

Advantageously, this method enables manufacturing a copper-free CdTe based thin film solar cell device by ex-situ doping.

According to the invention, a substrate means any basis the CdTe based absorber layer is deposited onto in step b). That is, the substrate may comprise a transparent base substrate, for instance of glass, a transparent front electrode and further layers like buffer layers, window layers or any else. In other embodiments, the substrate may comprise a transparent or opaque back electrode and further layers like buffer layers or any else. That is, the substrate may be glass, polymeric, metallic, or ceramic material or any other material.

A CdTe based absorber layer means a layer or layer stack comprising at least one layer of the composition CdTe, CdSe, Cd₁₋ₓHgₓTe, Cd₁₋ₓMnₓTe CdSeₓTe₁₋ₓ with x varying between 0≤x≤0.5. A layer stack is deposited in embodiments, for instance by subsequently depositing one or a plurality of layers, for instance layers of CdSe and CdTe, followed by interdiffusion of the different layers if desired, or in one undivided process. In embodiments, the CdTe based absorber layer is deposited as a doped CdTe based absorber layer, doped with any suitable element known from state of the art. In further embodiments, depositing a doped CdTe based absorber layer may be achieved by any known method, for instance by depositing a doping source layer before, after or between depositing the CdTe based absorber layer or by co-deposition of a CdTe based absorber layer and at least one doping material. Advantageously, the CdTe based absorber layer is doped with any known element excluding copper. In further embodiments, the CdTe based absorber layer is doped with a group 15 element, preferably with P, As, Sb and V. In further embodiments, the CdTe based absorber layer is deposited onto the provided substrate with the aforementioned layers on top using any technique known from the prior art, comprising, but not limited to, physical vapour deposition, e.g. sputtering, evaporation or sublimation, electrodeposition, or any else. In embodiments, the CdTe based absorber layer is deposited with a thickness from 1 μm to 5 μm, preferably with a thickness from 2 μm to 4 μm.

In embodiments, the activation treatment in step c) is performed by applying an activation agent like for instance CdCl2 onto the CdTe based absorber layer by wet chemical methods or by vacuum evaporation followed by annealing in air atmosphere at a temperature in the range of 380° C. to 460° C. for a duration in the range of 5 minutes to 30 minutes and a cleaning step. In embodiments, step c) is performed after step b) and/or after step d).

In embodiments, step d) is performed before or after the activation treatment in step c). In preferred embodiments, step d) is performed after step c). Advantageously, the applied X-halogen is therefore not heated above its boiling point which would be reached during the activation treatment in step c).

In step d) the X-halogen is applied in liquid or gaseous form. Examples for X-halogens, wherein X is selected out of a group consisting of P, As, Sb and V are but not limiting PCl₃, AsCl₃, SbCl₃, VF₅, VCl₄, VCl₃. A X-halogen in liquid form means a X-halogen present as liquid phase, a X-halogen solution, a X-halogen suspension or a gel-like X-halogen.

A X-halogen present as liquid phase is for instance PCl₃, AsCl₃, VF₅, VCl₄, which are present as liquid phase at room temperature.

A X-halogen solution means an X-halogen dissolved in a solvent. The solvent is thereby suitable for solving the X-halogen. A suitable solvent for VF₅ is for instance water, for AsCl₃ and PCl₃ a suitable solvent is for instance ether.

A gel-like X-halogen means a X-halogen present as liquid phase or a X-halogen solution each comprising an additional gelling agent and a viscosity in the range of 1 mPa s to 250 mPa s, preferably 2 mPa s to 50 mPa s. Such a gelling agent may be for instance poly-ethylene-glycol (PEG) or other gelling agents known by an expert.

A X-halogen suspension means a X-halogen solution, a X-halogen present as liquid phase or a gel-like X-halogen each with dispersed solid particles. Such solid particles provide further doping elements and are suitable for forming Cd-and/or Se-rich layers close to the back contact, in other words the solid particles may comprise at least Cd and/or Se and doping elements, like for instance a group 15 element, preferably P, As, Sb and V. In embodiments, the solid particles may be for instance doping activation agents, like Cd₂As₃ or As₂Se₃. In embodiments, the disperse solid particles have a particle size in the range of 1 μm to 100 μm. In further embodiment, the X-halogen suspension comprises 10 mg to 10 g of solid particles.

In further embodiments, the X-halogen solution, the X-halogen suspension or the gel-like X-halogen comprises the X-halogen with a concentration in the range of 0.1 mmol/l to 50 mmol/l.

In some embodiments, in step d), alternatively or additionally, a X-hydride is applied to the CdTe based absorber layer, wherein X is selected out of a group consisting of P, As, Sb and V. Examples for X-hydrides but not limiting are PH₃, AsH₃, SbH₃, BiH₃, VH₅. Advantageously, X-hydrides are present as gaseous phase at room temperature, i.e. in a temperature range between 18° C. to 40° C.

According to the invention, an inert atmosphere means an atmosphere with an oxygen content below 50 ppm and free from humidity or a reducing atmosphere like Ar, N₂ or H₂ atmosphere. Vacuum means a pressure in the range of 10⁻⁴ Pa to 10⁴ Pa.

In embodiments, the back contact in step f) is deposited at elevated temperatures in the range of 200° C. to 300° C. In further embodiments, the back contact is deposited in vacuum. In some embodiments, the back contact is deposited as a single back contact layer or as a back contact layer stack. In further embodiments, a metal layer is deposited as back contact in step f).

In embodiments, the X-halogen is applied by known methods, like wet chemical impregnation, gaseous impregnation, dip coating, roller coating, etc.

In further embodiments, the method may comprise further steps known from state of the art to manufacture a free CdTe based thin film solar cell device, like for instance an NP etching step (phosphorus nitride etch) for forming a Te-rich surface portion on a CdTe based absorber layer.

In embodiments, the method further comprises a step g) of performing a dopant activation treatment under presence of at least one of the following materials: PCl₃, Cd₃P₂, AsCl₃, As₂Se₃ Cd₃As₂, SbCl₃, Sb₂Se₃ Cd₃Sb₂, VCl₃ or VCl₄ at 400° C. Advantageously, an overabundance of doping elements, like As or V for doping the CdTe based absorber layer is applied to achieve higher doping levels.

In further embodiments, step g) is performed after step e) and before step f). In some embodiments, step g) is performed in an inert atmosphere.

Under presence means that the atmosphere the dopant activation treatment is performed in contains at least one of the above-mentioned substances. In further embodiments, the atmosphere contains up to 10% at least one of those substances.

In embodiments, the method further comprises a step h) of depositing a layer comprising at least one element X, wherein X is selected out of the group consisting of P, As, Sb and V. The step h) is performed before step f) and after step d). In embodiments, step h) may be performed before step e).

Advantageously, a p⁺layer is formed reducing the Schottky barrier at the interface of the CdTe based absorber layer and the back contact in following process steps.

In embodiments, the layer comprising at least one of the element X and deposited in step h) may be a layer comprising X as a compound or as doping element.

In embodiments, a layer comprising at least one element X, wherein X is P, As or Sb is deposited in step h). Such a P, As or Sb comprising layer may be for instance but not limiting As₂Se₃, As₂Te₃, Sb₂Te₃ or N, P, As, Sb doped ZnTe.

Advantageously, the layer serves as source layer providing further doping elements for doping the CdTe based absorber layer in following process steps. In some embodiments, the layer also serves as sacrificial layer for providing a Te-rich intermediate layer towards the back contact in following process steps.

In further embodiments, the layer is deposited with a thickness in the range of 10 nm to 100 nm in step h).

In embodiments, the layer in step h) may be deposited by known methods, for instance but not limiting to, by sputtering. In further embodiments, the layer is deposited in step h) in an inert atmosphere or vacuum. In embodiments, the layer is deposited in step h) at a temperature in the range of 100° C. to 250° C.

In embodiments, after step h), an annealing treatment is performed in step i). Advantageously, this enables providing of further doping elements for doping the CdTe based absorber layer, distribution of the doping elements within the CdTe based absorber layer and in some embodiments forming a Te-rich intermediate layer towards the back contact.

In embodiments, step i) is performed after step f). In this case, step i) also serves as back contact annealing treatment.

In embodiments, the annealing treatment in step i) is performed at temperatures in the range of 200° C. to 300° C. for a duration in the range of 20 minutes to 60 minutes in an inert atmosphere or vacuum.

In embodiments, the back contact is deposited as a back contact layer stack at least comprising a first back contact layer and a second back contact layer.

In embodiments, depositing the first back contact layer is performed at temperatures in the range of 200° C. to 300° C. in an inert atmosphere or vacuum.

In further embodiments, the first back contact layer is deposited with a thickness in the range of 5 nm to 100 nm.

In embodiments, ZnTe is deposited as the first back contact layer.

In further embodiments, ZnTe may be deposited as a doped ZnTe layer, for instance doped with P, As, Sb and/or N. In some embodiments, a doped ZnTe layer comprises up to 5 wt-% of at least one doping element.

In embodiments, a metal layer is deposited as the second back contact layer.

In further embodiments, the second back contact layer may be deposited at temperatures in the range of 100° C. to 300° C. in an inert atmosphere or vacuum.

Advantageously, an annealing treatment after depositing the back contact in step f) is not necessary, saving process steps.

In further embodiments, a highly conductive metal with a sheet resistance of <1 Ohm/sq is deposited as the metal layer. Examples for such metal layers are Mo or Al but not limiting.

In further embodiments, the second back contact layer is deposited with a thickness in the range of 10 nm to 100 nm.

In embodiments, the second back contact layer is deposited immediately after the first back contact layer. In further embodiments, an intermediate back contact layer is deposited after the first back contact layer and before the second back contact layer. In embodiments, the intermediate back contact layer is a metal nitride layer, for instance MoN or AlN but not limiting. In further embodiments, the metal nitride intermediate back contact layer comprises the same metal as the metal layer deposited as the second back contact layer. In further embodiments, the intermediate back contact layer is deposited with a thickness in the range of 10 nm to 50 nm. In embodiments, the intermediate back contact layer is deposited at a temperature in the range of 10° C. to 100° C. in an inert atmosphere or vacuum.

For realization of the invention, it is advantageous to combine the described embodiments and features of the claims as described above. However, the embodiments of the invention described in the foregoing description are examples given by way of illustration and the invention is nowise limited thereto.

Any modification, variation and equivalent arrangement as well as combinations of embodiments should be considered as being included within the scope of the invention.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 shows an exemplary process flow of a method according to the invention.

### DETAILED DESCRIPTION

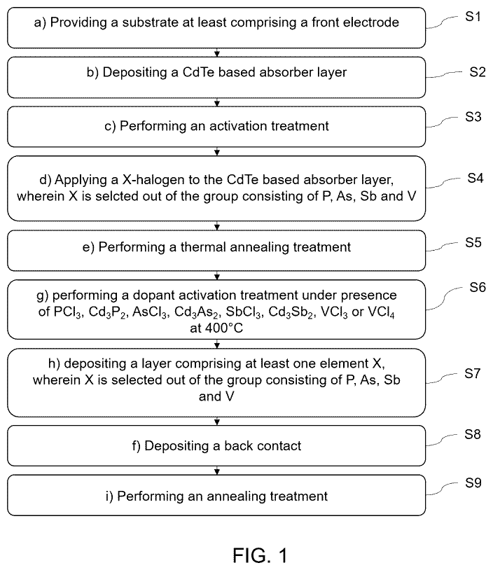

A process flow of an exemplary embodiment of a method for manufacturing a copper-free CdTe based thin film solar cell device according to the invention is shown in FIG. 1. First in step S1, a substrate at least comprising a front electrode is provided (step a)), wherein the substrate is a glass substrate with a front electrode made of tin oxide on top. In other embodiments, the substrate may comprise further layers like buffer layers, window layers or any else. In the following step S2, a CdTe based absorber layer is deposited by closed space sublimation (step b)). The CdTe based absorber layer is thereby deposited as a single layer of CdTe with a thickness of 3.5 μm. In other embodiments, the CdTe based absorber layer may be deposited as a layer stack of alternating, individual layers of CdSe and CdTe with a total thickness of the layer stack of 3.5 μm. In other embodiments, it is also possible to deposit a doped CdTe based absorber layer, wherein doping may be achieved by methods known from state of the art, for instance by co-deposition of a CdTe based absorber layer and at least one doping material or any other known method. Following in step S3, an activation treatment is performed (step c)) by applying an activation agent onto the CdTe based absorber layer by a wet chemical method followed by annealing in air atmosphere at a temperature in the range of 380° C. to 470° C. for a duration in the range of 7 minutes to 35 minutes and a cleaning step. In the next step S4, a X-halogen is applied to the CdTe based absorber layer, wherein X is selected out of the group consisting of P, As, Sb and V (step d)). In the example, AsCl₃ is applied as the X-halogen in liquid form as a solution by a wet chemical method under inert conditions known from state of the art. Following in step S5, a thermal treatment after step d) is performed (step e)) at a temperature of 80° C. in N2 atmosphere for a duration in the range of 30 minutes. Next in step S6, a dopant activation treatment under presence of at least one of the following materials is performed (step g)): PCl₃, Cd₃P₂, AsCl₃, Cd₃As₂, SbCl₃, Cd₃Sb₂, VCl₃ or VCl₄. In the example, the dopant activation treatment is performed under presence of Cd₃As₂ at 400° C. in vacuum. Step S6 is especially useful if wet chemical doping is performed in step d), as in the present example, or if CdSe was deposited during deposition of the CdTe based absorber layer in step b). In other embodiments, step g), i.e. step S6, may be saved. Afterwards in step S7, a layer comprising at least one element X, wherein X is selected out of the group consisting of P, As, Sb and V is deposited before step f) (step h)). In the example, an As₂Se₃ layer is deposited by sputtering with a thickness of 30 nm at a temperature of 250° C. Next in step S8, a back contact is deposited (step f)), wherein the back contact may be deposited as a layer stack. The back contact layer stack may comprise a first back contact layer, for instance an As doped ZnTe layer. However, in the present example, a ZnTe layer is not needed since the As₂Se₃ layer is deposited. In the other way, if no As₂Se₃ layer is deposited, a X-doped ZnTe layer would be advantageous or even necessary. The back contact layer stack may comprise an intermediate back contact layer, deposited directly after the first back contact layer or, in the present example, after depositing the As₂Se₃ layer. In the present example, the intermediate back contact layer is deposited by sputtering Mo at room temperature in the presence of nitrogen to form a 30 nm MoNₓ layer. In the present example, the back contact layer stack is finished by depositing a second back contact layer by sputtering a Mo layer with a thickness of 250 nm. Afterwards in step S9, an annealing treatment is performed (step i)) at a temperature of 200° C. in air for 30 minutes.

What is claimed is:

1. A method for manufacturing a copper-free CdTe based thin film solar cell device at least comprising the following steps
Providing a substrate at least comprising a front electrode,
Depositing a CdTe based absorber layer,
Performing an activation treatment,
Applying a X-halogen to the CdTe based absorber layer, wherein X is selected out of a group consisting of P, As, Sb and V;
Performing a thermal treatment after step d),
Depositing a back contact,
characterized in that, the thermal treatment in step e) is performed before step f) and at temperatures in the range of 40° C. to 120° C. in inert atmosphere or vacuum for a duration in the range of 10 to 60 minutes.

2. The method according to claim 1, characterized in that the method further comprises a step g) of performing a dopant activation treatment under presence of at least one of the following materials: PCl₃, Cd₃P₂, AsCl₃, As₂Se₃ Cd₃As₂, SbCl₃, Cd₃Sb₂, Sb₂Se₃ VCl₃ or VCl₄ at 400° C.

3. The method according to claim 1 or 2, characterized in that the method further comprises a step h) of depositing a layer comprising at least one element X, wherein X is selected out of the group consisting of P, As, Sb and V before step f).

4. The method according to any of the previous claims, characterized in that after step h) an annealing treatment is performed in step i).

5. The method according to claim 4, characterized in that the annealing treatment in step i) is performed at temperatures in the range of 200° C. to 300° C. for a duration in the range of 20 minutes to 60 minutes in inert atmosphere or vacuum.

6. The method according to any of the previous claims, characterized in that the back contact is deposited as a back contact layer stack at least comprising a first back contact layer and a second back contact layer.

7. The method according to claim 6, characterized in that ZnTe is deposited as the first back contact layer.

8. The method according to claim 6 or 7, characterized in that a metal layer is deposited as the second back contact layer.
